(19) United States
(12) Patent Application Publication
(10) Pub. No.: US 2017/0345993 A1
(43) Pub. Date: Nov. 30, 2017

(54) PIEZOELECTRIC DEVICE

(71) Applicant: NIHON DEMPA KOGYO CO., LTD., Tokyo (JP)

(72) Inventor: KENICHI KIKUCHI, Saitama (JP)

(73) Assignee: NIHON DEMPA KOGYO CO., LTD., Tokyo (JP)

(21) Appl. No.: 15/599,474

(22) Filed: May 19, 2017

(30) Foreign Application Priority Data
May 25, 2016 (JP) 2016-104460

(51) Int. Cl. H01L 41/09; H01L 41/18; H01L 41/08; H01L 41/313; H01L 41/047

(52) U.S. Cl. CPC H01L 41/0913; H01L 41/313; H01L 41/0477; H01L 41/0815; H01L 41/18

(57) ABSTRACT

A piezoelectric device includes a piezoelectric vibrating piece, a base, a wire, a conductive adhesive, and a buffer layer. The piezoelectric vibrating piece includes excitation electrodes and extraction electrodes at both principal surfaces. The base includes the piezoelectric vibrating piece and a first wiring electrode and a second wiring electrode connected to the extraction electrodes. The wire connects the extraction electrode on a surface opposite to a side of the base among the extraction electrodes to one wiring electrode of the first wiring electrode and the second wiring electrode. The conductive adhesive connects the extraction electrode at the base side among the extraction electrodes to the other wiring electrode among the first wiring electrode and the second wiring electrode. The buffer layer reduces stress of the wire between the extraction electrode to which the wire is connected and the piezoelectric vibrating piece.

### CROSS-REFERENCE TO RELATED APPLICATIONS

This application is based on and claims priority under 35 U.S.C. §119 to Japanese Patent Application No. 2016-104460, filed on May 25, 2016, the entire content of which is incorporated herein by reference.

### TECHNICAL FIELD

This disclosure relates to a crystal unit and a crystal controlled oscillator as a piezoelectric device, and especially relates to a piezoelectric device that employs a wire bonding technique.

### DESCRIPTION OF THE RELATED ART

Various pieces of electronic equipment such as mobile phones and personal computers often use a crystal unit and a crystal controlled oscillator to select and control a frequency or for a similar purpose.

A typical crystal unit includes a crystal element, which has a rectangular shape in plan view, and a base. The crystal element includes excitation electrodes and extraction electrodes on both principal surfaces. The base includes this crystal element and a first wiring electrode and a second wiring electrode connected to the above-described extraction electrodes. Then, one of this type of crystal units includes the crystal element in the base by two kinds of mounting means: conductive adhesive and wire bonding.

For example, in Japanese Unexamined Patent Application Publication No. 2010-147625, bonding and securing an extraction electrode on one surface to a first wiring electrode on a base with a conductive adhesive secures a crystal element to the base. Then, an extraction electrode disposed on another surface of this crystal element is connected to a second wiring electrode on the base by wire bonding.

As described above, when one of the secured connections between the crystal element and the base is performed by the wire bonding, compared with a case where all of the secured connections between the crystal element and the base is performed with the conductive adhesive, it is considered to ensure reduction of stress from the secured portion of the crystal to the crystal element. However, by considering that a request for downsizing the crystal unit increases more than ever, for the crystal unit that employs the wire bonding, further reduction of the stress caused by the wire bonding will be an important matter.

A need thus exists for a piezoelectric device which is not susceptible to the drawback mentioned above.

### SUMMARY

According to an aspect of this disclosure, there is provided a piezoelectric device. The piezoelectric device includes a piezoelectric vibrating piece, a base, a wire, a conductive adhesive, and a buffer layer. The piezoelectric vibrating piece includes excitation electrodes and extraction electrodes at both principal surfaces. The base includes the piezoelectric vibrating piece and a first wiring electrode and a second wiring electrode connected to the extraction electrodes. The wire connects the extraction electrode on a surface opposite to a side of the base among the extraction electrodes to one wiring electrode of the first wiring electrode and the second wiring electrode. The conductive adhesive connects the extraction electrode at the base side among the extraction electrodes to the other wiring electrode among the first wiring electrode and the second wiring electrode. The buffer layer reduces stress of the wire between the extraction electrode to which the wire is connected and the piezoelectric vibrating piece.

### BRIEF DESCRIPTION OF THE DRAWINGS

The foregoing and additional features and characteristics of this disclosure will become more apparent from the following detailed description considered with reference to the accompanying drawings, wherein:

FIG. 1A is a plan view of a piezoelectric device 10 in a first embodiment, and FIG. 1B is a sectional drawing of the piezoelectric device 10;

FIG. 2A is an enlarged plan view of a part of the piezoelectric device 10, and FIG. 2B is an enlarged sectional drawing of the part of the piezoelectric device 10;

FIG. 3A is a plan view of a piezoelectric device 40 in a second embodiment, and FIG. 3B is a sectional drawing of the piezoelectric device 40; and

FIG. 4A is a plan view of a piezoelectric device 50 (oscillator) in a third embodiment, FIG. 4B is a sectional drawing of a part of the piezoelectric device 50, and

FIG. 4C is a sectional drawing illustrating another configuration of the oscillator.

### DETAILED DESCRIPTION

The following describes embodiments of this disclosure with reference to the drawings. Each drawing used in the descriptions is merely illustrated schematically for understanding the disclosure. In each drawing used in the descriptions, like reference numerals designate corresponding or identical elements, and therefore such elements will not be further elaborated here. Shapes, dimensions, materials, and a similar factor described in the following embodiments are merely preferable examples within the scope of the disclosure. Therefore, the disclosure is not limited to only the following embodiments.

### 1. First Embodiment

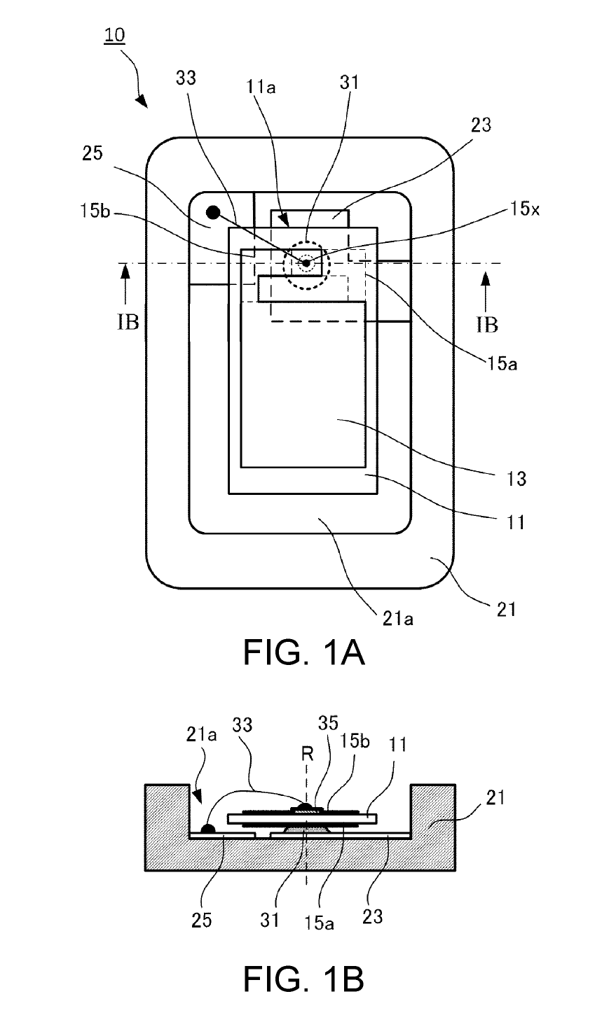

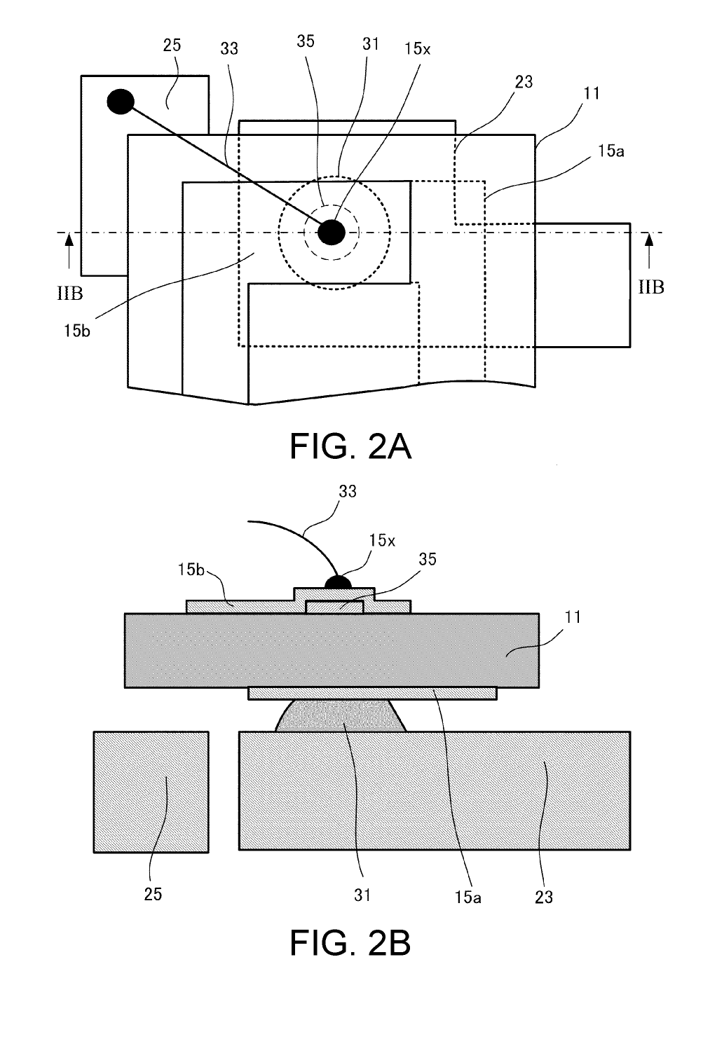

FIG. 1A is a plan view illustrating a piezoelectric device 10 in a first embodiment, and FIG. 1B is a sectional drawing of the piezoelectric device 10 taken along the line IB-IB in FIG. 1A. FIG. 2A is an enlarged plan view of a part of FIG. 1A, and FIG. 2B is a sectional drawing taken along the line IIB-IIB in FIG. 2A. Note that these drawings omit the illustration of a lid provided to the piezoelectric device.

This piezoelectric device 10 uses a crystal element as a piezoelectric vibrating piece. Specifically, this piezoelectric device 10 includes a crystal element 11, which has a rectangular shape in a planar shape, excitation electrodes 13, which are disposed on both principal surfaces of this crystal element 11, extraction electrodes 15a and 15b, a base 21, and a first and a second wiring electrodes 23 and 25. The extraction electrodes 15a and 15b are each extracted from the excitation electrodes 13 up to near one side 11a of the crystal element 11. The base 21 includes the crystal element 11 and has a rectangular shape in a planar shape. The first and the second wiring electrodes 23 and 25 are disposed on the base 21 and are connected to the extraction electrodes 15a and 15b. Furthermore, this piezoelectric device 10 includes a mounting structure by a conductive adhesive 31 and a wire 33 that are feature of this disclosure, and a buffer layer 35. These configuration components 31, 33, and 35 are described later in detail.

In this embodiment, the base 21 has a concave portion 21a and includes the crystal element 11 inside this concave portion 21a. Furthermore, this base 21 includes a mounting terminal (not illustrated) on an outside bottom surface. Then, the first wiring electrode 23 and the second wiring electrode 25 are connected to the mounting terminal (not illustrated) with a via wiring (not illustrated) disposed at a bottom plate part of the base 21. In this case, this base 21 is configured of a ceramic package.

The crystal element 11 is securely connected to the first wiring electrode 23 with the conductive adhesive 31, at an end part on the one side 11a side on one surface of the crystal element 11 and a position of the extraction electrode 15a at a part corresponding to approximate center in a direction along this one side 11a. As the conductive adhesive 31, various kinds of conductive adhesives such as polyimide-based, epoxy-based, and silicone-based conductive adhesives can be used. However, it is preferable to use the silicone-based conductive adhesive. For the silicone-based conductive adhesive, compared with other conductive adhesives, influence of stress to the crystal element is small. Thus, in combination with the buffer layer in this disclosure, the silicone-based conductive adhesive ensures stress reduction from the secured portion to the crystal element. The excitation electrodes 13 and the extraction electrodes 15a and 15b can be each formed of, for example, laminated films of a chrome film and a gold film from the crystal element side.

The extraction electrode 15b, which is on the other surface of this crystal element 11, and the second wiring electrode 25 are connected with the wire 33 by a wire bonding method. The securing with the conductive adhesive and the wire bonding are performed such that the secured position of the conductive adhesive 31 overlaps the bonding position on the crystal element side with the wire 33 by the wire bonding in the crystal element 11 thickness direction (a direction along a line segment R in FIG. 1B) (includes the case where the secured position and the bonding position almost overlap). The wire bonding method is not especially limited, and a method such as a ball bonding method and a wedge bonding method can be used.

Furthermore, this disclosure, as illustrated in the enlarged figures of FIG. 2A and FIG. 2B, includes the buffer layer 35 to reduce the stress of the wire 33 between a region larger than a region 15x connected to the wire 33 and including the region 15x, of the extraction electrode 15b, and the crystal element 11. This buffer layer 35 can be formed of various materials insofar as these materials can reduce the stress and ensure close contact with the extraction electrode 15b. A preferred material example that forms this buffer layer 35 includes a polymer-based material. For example, resin referred to as permanent resist or permanent photoresist is preferred. It is because that usage of the permanent resist can obtain advantages such that patterning into an optional planar shape is ensured by a photolithography technology, adhesion with the crystal element 11 is also excellent, and moreover, coating by the extraction electrode 15b and adhesion of the extraction electrode 15b are also ensured.

The permanent resist, specifically, includes permanent resist using polyimide resin and permanent resist using epoxy resin. Before forming the extraction electrode 15b after forming the buffer layer 35 with the permanent resist, it is preferred to perform a surface modifying process such that a surface of this buffer layer 35 is treated with, for example, argon ion to roughen the surface. It is because that this increases the adhesion to the buffer layer 35 of the extraction electrode 15b.

The planar shape of the buffer layer 35 is optional corresponding to a planar shape of a connecting portion to the crystal element 11 of the wire 33. For example, when the planar shape of the connecting portion to the crystal element 11 of the wire 33 has a circular shape, it is preferred that the planar shape of the buffer layer 35 also has a circular shape slightly larger than the above-described circular shape. Obviously, an angular shape or an elliptical shape in plan view is possible.

To prevent gas from outputting from the buffer layer 35, it is preferred to completely cover the buffer layer 35 with the extraction electrode 15b.

It is preferred to determine a thickness of the buffer layer 35 by considering, for example, how the stress of the wire influences the crystal element, how the stress of the buffer layer 35 influences the crystal element 11, and ease of coating the buffer layer 35 with the extraction electrode. The thickness of the buffer layer 35 may be, for example, 1 to 10 μm, preferably 1 to 5 μm, and more preferably 1 to 3 μm, although it is not limited to these.

The piezoelectric device 10 in the first embodiment includes the buffer layer 35 as a lower layer of the region 15x to which the wire 33 is secured, of the extraction electrode 15b. Thus, compared with a case not including the buffer layer 35, this can reduce the stress to the crystal element 11 of the wire 33. Thereby reducing characteristic deterioration of the crystal unit caused by the above-described stress can be expected.

### 2. Second Embodiment

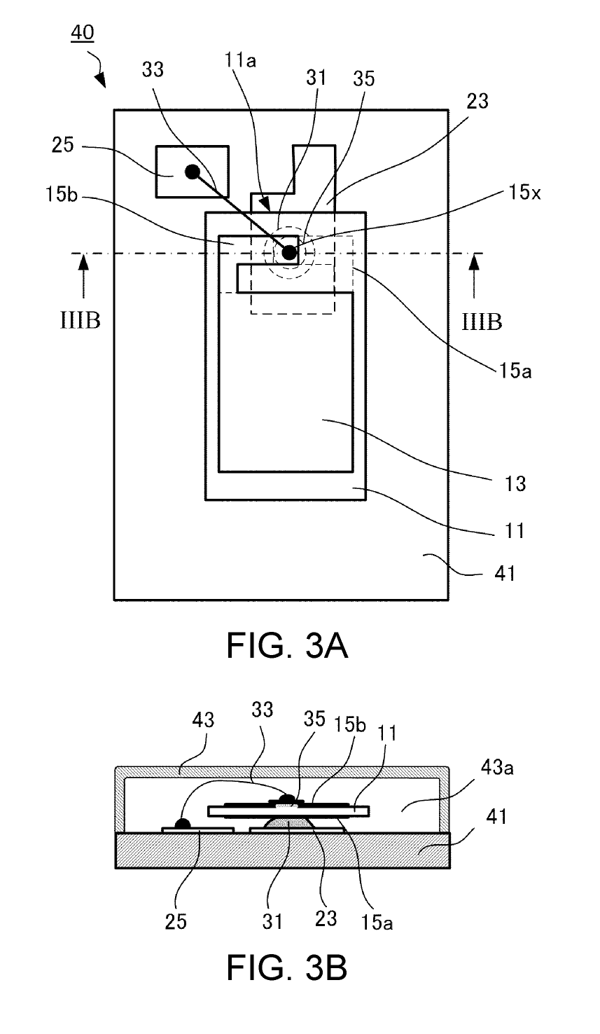

In the above-described first embodiment, the base having the concave portion 21a, which contains the crystal element 11, and a dike, which are disposed surrounding the concave portion 21a, is used as the base 21, and the piezoelectric device is sealed with a lid member at the above-described dike. However, this disclosure is applicable to a piezoelectric device that employs a base with another structure. FIG. 3A and FIG. 3B are drawings for the explanation, especially FIG. 3A is a plan view of a piezoelectric device 40 of an embodiment that employs the base with the other structure, and FIG. 3B is a sectional drawing taken along the line IIIB-IIIB in FIG. 3A.

The piezoelectric device 40 of this second embodiment includes a flat-plate-shaped base 41 and a lid member 43 (see FIG. 3B). The base 41 is a base for placing the crystal element 11 and is provided with the first wiring electrode 23 and the second wiring electrode 25. The lid member 43 has a concave portion 43a that contains the crystal element 11. This piezoelectric device 40, similarly to the first embodiment, also includes the buffer layer 35 between the extraction electrode 15b and the crystal element 11. The base 41 is sealed with the lid member 43 at the edges (FIG. 3B).

The flat-plate-shaped base 41 can be made of, for example, ceramics. The lid member 43 can be made of, for example, a metallic member formed by drawing process. Any given preferable method may be employed as a sealing method of the base 41 with the lid member 43. For example, the following method can be employed. Eutectic alloys (not illustrated) are provided on the edges of the base 41 to bond the lid member 43 with the eutectic alloys. Alternatively, a method that connects the edges of the base 41 to the lid member 43 with a material such as an adhesive can be employed.

### 3. Third Embodiment

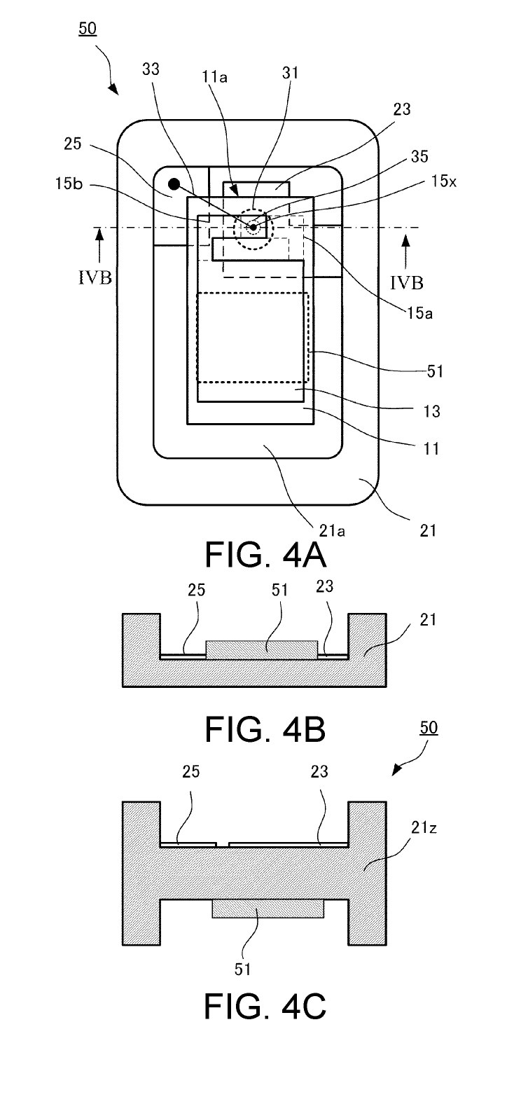

This disclosure is also applicable to a crystal controlled oscillator. FIG. 4A to FIG. 4C are the explanatory drawings. Especially, FIG. 4A is a schematically plan view of an oscillator 50 to which this disclosure is applied, and FIG. 4B is a sectional drawing taken along the line IVB-IVB in FIG. 4A. FIG. 4C is a sectional drawing illustrating an outline of the oscillator 50 that employs a container 21z having a so-called H-shaped structure, which has a shape to house a crystal element and components for an oscillator circuit, for example, an IC chip for oscillator circuit in different chambers. FIG. 4B and FIG. 4C omit the crystal element 11, the electrodes 13, 15a, and 15b, the conductive adhesive 31, and similar member, for clearly indicating a member 51 such as the IC chip for oscillator circuit. The base 21 and the container 21z obviously include wiring for the member 51 for oscillator circuit, however the explanation is omitted.

Such crystal controlled oscillator 50 also includes the buffer layer 35 according to this disclosure between the extraction electrode 15b and the crystal element 11 in a structure where the crystal element 11 and the extraction electrode 15b are connected with the wire.

While the embodiments of the piezoelectric device according to this disclosure are described above, this disclosure is not limited to the above-described embodiments. For example, in the above-described example, the secured position of the conductive adhesive and the secured position of the wire are positioned as overlapping in the thickness direction of the crystal element. This configuration secures the crystal element to approximately one position planarly, thus ensuring reduction of the influence of the stress from the secured portion. However, depending on cases, both positions may be configured without overlapping.

To embody this disclosure, it is preferable that the buffer layer is a layer made of resin. As such resin, it is preferable to use a resin referred to as permanent resist.

The piezoelectric device in this disclosure includes a crystal unit that exhibits thickness-shear vibration, typically an AT-cut crystal unit, a twice rotated crystal unit (for example, an SC-cut crystal unit), and an oscillator including these crystal units and a member for oscillator circuit, and further, a vibrator and an oscillator that employ a piezoelectric material other than the crystal, and is a piezoelectric device that employs the wire bonding.

With the piezoelectric device in this disclosure, the stress to the piezoelectric vibrating piece of the wire can be reduced to the extent including the buffer layer, compared with a case of not including the buffer layer, thereby reducing characteristic deterioration of the piezoelectric device caused by the stress can be expected.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric device comprising:
a piezoelectric vibrating piece that includes excitation electrodes and extraction electrodes at both principal surfaces;
a base that includes the piezoelectric vibrating piece and a first wiring electrode and a second wiring electrode connected to the extraction electrodes;
a wire that connects the extraction electrode on a surface opposite to a side of the base among the extraction electrodes to one wiring electrode of the first wiring electrode and the second wiring electrode;
a conductive adhesive that connects the extraction electrode at the base side among the extraction electrodes to the other wiring electrode among the first wiring electrode and the second wiring electrode; and
a buffer layer that reduces stress of the wire between the extraction electrode to which the wire is connected and the piezoelectric vibrating piece.

2. The piezoelectric device according to claim 1, wherein
the buffer layer is made of a permanent resist.

3. The piezoelectric device according to claim 1, wherein
the conductive adhesive is a silicone-based conductive adhesive.

4. The piezoelectric device according to claim 1, wherein:
the piezoelectric vibrating piece has a rectangular shape,
a secured position of the conductive adhesive and a secured position of the wire are at an end portion at one short side of the rectangular-shaped piezoelectric vibrating piece and near a center along the short side, and
the secured position of the conductive adhesive and the secured position of the wire at the piezoelectric vibrating piece overlap in a thickness direction of the piezoelectric vibrating piece.
